(19) United States
(12) Patent Application Publication
(10) Pub. No.: US 2022/0169800 A1
(43) Pub. Date: Jun. 2, 2022

(54) EPOXY-CONTAINING SILOXANE-MODIFIED RESIN, PACKAGE MATERIAL, AND PACKAGE STRUCTURE

(71) Applicant: INDUSTRIAL TECHNOLOGY RESEARCH INSTITUTE, Hsinchu (TW)

(72) Inventors: Wen-Bin CHEN, Zhudong Township (TW); Ying-Nan CHAN, Erlin Township (TW); Kai-Chi CHEN, Zhubei City (TW); Chih-Hao LIN, Taoyuan City (TW)

(73) Assignee: INDUSTRIAL TECHNOLOGY RESEARCH INSTITUTE, Hsinchu (TW)

(21) Appl. No.: 17/133,927

(22) Filed: Dec. 24, 2020

(30) Foreign Application Priority Data
Nov. 30, 2020 (TW) 109141971

(51) Int. Cl. C08G 77/00; C08L 63/00; C09D 163/00

(52) U.S. Cl. CPC C08G 77/70; C09D 163/00; C08L 63/00

(57) ABSTRACT

An epoxy-containing siloxane-modified resin, a package material, and a package structure are provided. The epoxy-containing siloxane-modified resin is formed by reacting a hydroxy terminated siloxane compound with a siloxane resin, and then reacting with an epoxy silane. The hydroxy terminated siloxane compound and the siloxane resin have a molar ratio of 5:1 to 10:1, and the epoxy silane and the siloxane resin have a molar ratio of 2:1 to 4:1.

### CROSS REFERENCE TO RELATED APPLICATIONS

The present application is based on, and claims priority from, Taiwan Application Serial Number 109141971, filed on Nov. 30, 2020, the disclosure of which is hereby incorporated by reference herein in its entirety.

### TECHNICAL FIELD

The technical field relates to a package material.

### BACKGROUND

The major functions of semiconductor package material include protecting chips, protecting lines, and increasing the reliability of the package element. There are three possible types of molding compound with a large area: a solid molding compound, a liquid molding compound (LMC), and a sheet film molding compound. LMC is prevalent on the market due to its advantages which include large area, high density, thin line, multi-chip package integration, and absence of dust.

In order to make sure that the thermal expansion coefficient of the adhesive material (i.e. the package material) is similar to that of the silicon wafer, at least 85 wt % of inorganic powder should be added to the wafer-level package material to lower the thermal expansion coefficient of the adhesive material. However, the large amount of inorganic powder added may result in a dramatic increase in the viscosity and the stress of the package material (especially during large-area packaging), thereby negatively affecting processability and package reliability. The general improvement involves adding a soft substance of high molecular weight to the composition of the adhesive material to lower its stress, but this method may lower the Tg of the adhesive material.

Accordingly, a resin used for adding to composition of the adhesive material can maintaining the Tg of the adhesive material, enhancing compatibility with the composition of the adhesive material, and reducing stress and warpage of the adhesive material is called for.

### SUMMARY

One embodiment of the disclosure provides an epoxy-containing siloxane-modified resin, being formed by reacting a hydroxy terminated siloxane compound with a siloxane resin, and then reacting with an epoxy silane; wherein the hydroxy terminated siloxane compound and the siloxane resin have a molar ratio of 5:1 to 10:1, and the epoxy silane and the siloxane resin have a molar ratio of 2:1 to 4:1.

One embodiment of the disclosure provides a package material, including: (a) 1 part by weight of epoxy-containing siloxane-modified resin; (b) 3 to 30 parts by weight of epoxy resin; (c) 3 to 30 parts by weight of anhydride curing agent; and (d) 50 to 500 parts by weight of inorganic powder, wherein (a) epoxy-containing siloxane-modified resin is formed by reacting a hydroxy terminated siloxane compound with a siloxane resin, and then reacting with an epoxy silane; wherein the hydroxy terminated siloxane compound and the siloxane resin have a molar ratio of 5:1 to 10:1, and the epoxy silane and the siloxane resin have a molar ratio of 2:1 to 4:1.

One embodiment of the disclosure provides a package structure, including: a wafer; a package film covering the wafer, wherein the package film is formed by curing a package material, wherein the package material includes: (a) 1 part by weight of epoxy-containing siloxane-modified resin; (b) 3 to 30 parts by weight of epoxy resin; (c) 3 to 30 parts by weight of anhydride curing agent; and (d) 50 to 500 parts by weight of inorganic powder, wherein (a) epoxy-containing siloxane-modified resin is formed by reacting a hydroxy terminated siloxane compound with a siloxane resin, and then reacting with an epoxy silane; wherein the hydroxy terminated siloxane compound and the siloxane resin have a molar ratio of 5:1 to 10:1, and the epoxy silane and the siloxane resin have a molar ratio of 2:1 to 4:1.

A detailed description is given in the following embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

One embodiment of the disclosure provides an epoxy-containing siloxane-modified resin, being formed by reacting a hydroxy terminated siloxane compound with a siloxane resin, and then reacting with an epoxy silane. The reaction order is necessary to form the epoxy-containing siloxane-modified resin. For example, if the hydroxy terminated siloxane compound, the siloxane resin, and the epoxy silane are simultaneously mixed together to react, the hydroxy terminated siloxane compound and the epoxy silane may firstly react (e.g. ring-opening reaction), and the product will be free of any epoxy group. Alternatively, the simultaneous mixing and reacting may form a product with a molecular weight that is too low.

The hydroxy terminated siloxane compound and the siloxane resin have a molar ratio of 5:1 to 10:1, and the epoxy silane and the siloxane resin have a molar ratio of 2:1 to 4:1. If the amount of the hydroxy terminated siloxane compound is too low, the molecular weight of the product will be too low to reduce the stress of the package material. If the amount of the hydroxy terminated siloxane compound is too high, the viscosity of the product will be too high to be compatible with the composition of the adhesive material. If the amount of the epoxy silane is too low, the compatibility of the product with the composition of the adhesive material will be poor. If the amount of the epoxy silane is too high, the excessive epoxy silane will remained to precipitate after curing the package material.

For example, the hydroxy terminated siloxane compound may have a chemical structure of

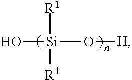

wherein each R¹ is independently C₁₋₅ alkyl group or

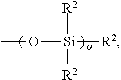

wherein each R² is independently C₁₋₅ alkyl group, n is 5-20, and o is 5-20. In one embodiment, the hydroxy terminated siloxane compound can be

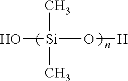

with a weight average molecular weight (Mw) of 400 to 700, 700 to 1500, or another suitable Mw.

In some embodiments, the siloxane resin has a chemical formula of R³₃SiO_{4/2}SiO_{3/2}SiOH, wherein R³ is C₁₋₆ alkyl group or phenyl group. If R³ is methyl group, the siloxane resin can be referred as MQ resin. For example, the siloxane resin can be SQO-200 commercially available from Gelest.

In some embodiments, the epoxy silane may have a chemical structure of

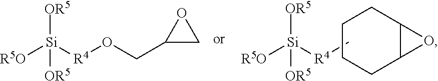

wherein R⁴ is C₁₋₅ alkylene group, and each R⁵ is independently C₁₋₅ alkyl group. For example, the epoxy silane can be

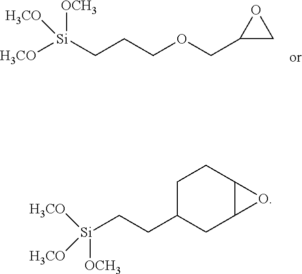 [SMILES: CO[Si](CCCOCC1CO1)(OC)OC ; CO[Si](CCC1CCC2OC2C1)(OC)OC]

In some embodiments, the epoxy-containing siloxane-modified resin has a weight average molecular weight of 7000 to 10000. If the weight average molecular weight of the epoxy-containing siloxane-modified resin is too low, the stress of the package material cannot be lowered. If the weight average molecular weight of the epoxy-containing siloxane-modified resin is too high, the viscosity of the product will be too high to be compatible with the composition of the adhesive material.

The epoxy-containing siloxane-modified resin can be added to composition of a package material to improve the properties of the package material (i.e. adhesive material). One embodiment of the disclosure provides a package material, including (a) 1 part by weight of epoxy-containing siloxane-modified resin; (b) 3 to 30 parts by weight of epoxy resin; (c) 3 to 30 parts by weight of anhydride curing agent; and (d) 50 to 500 parts by weight of inorganic powder, wherein (a) epoxy-containing siloxane-modified resin is formed by the method as described above, and the related description is not repeated here.

In some embodiments, (b) epoxy resin may include bisphenol A epoxy resin, bisphenol F epoxy resin, cycloaliphatic epoxy resin, novolac resin, naphthalene based epoxy resin, or a combination thereof. If the amount of (b) epoxy resin is too low, the Tg of the adhesive material will be too low. If the amount of (b) epoxy resin is too high, the Tg of the adhesive material will be too high.

In some embodiments, (c) anhydride curing agent may include methyl hexahydrophthalic anhydride, methyltetrahydrophthalic anhydride, hexahydrophthalic anhydride, benzophenonetetracarboxylic dianhydride, or a combination thereof If the amount of (c) anhydride curing agent is too low, the curing will be incomplete and the crosslink degree will be insufficient. If the amount of (c) anhydride curing agent is too high, the excessive curing agent will precipitate outside the bulk after curing.

In some embodiments, (d) inorganic powder may include silica powder, alumina powder, or another suitable powder of sub-micrometer scale to micrometer scale. If the amount of (d) inorganic powder is too low, the stress of the package material will not be reduced. If the amount of (d) inorganic powder is too high, the adhesive material will be hard and brittle (e.g. lack toughness). If (d) inorganic powder particle size is too small, the viscosity of the adhesive material will be too high. If (d) inorganic powder particle size is too large, the viscosity of the adhesive material will be too low.

In some embodiments, the package material further includes (e) 0.2 to 2 parts by weight of accelerator. For example, (e) accelerator may include 2-methyl imidazole, 2-ethyl-4-methyl imidazole, triethylamine, triphenyl phosphine, or a combination thereof. If the amount of (e) accelerator is too low, the curing will be incomplete due to insufficient crosslink degree. If the amount of (e) accelerator is too high, the adhesive material will be hard and brittle due to the excessively high degree of crosslinking.

In some embodiments, the package material further includes (f) 0.1 to 0.8 parts by weight of coupling agent. For example, (f) coupling agent may include glycidyloxypropyltrimethoxysilane, trimethoxy[2-(7-oxabicyclo[4.1.0]hept-3-yl)ethyl]silane, or a combination thereof. If the amount of (f) coupling agent is too low, the compatibility of the epoxy-containing siloxane-modified resin with the adhesive material formula resin is poor. If the amount of (f) coupling agent is too high, the excessive coupling agent will be precipitated.

One embodiment of the disclosure provides a package structure, including a wafer and a package film covering the wafer, in which the package film is formed by curing the package material. The package material is described above, and the related description is not repeated here.

In some embodiments of the disclosure, in the ion epoxy-containing siloxane-modified resin, the hydroxy terminated siloxane compound is introduced to tune the chain length between the siloxane resin, which can be applied as the package material to reduce the stress and the storage modulus of the package material, and maintain Tg and flowability of the package material (no flow mark in large-area packages, and completely filling the package area). In addition, the epoxy silane may increase the compatibility of the resin product with the adhesive material formula resin.

Below, exemplary embodiments will be described in detail so as to be easily realized by a person having ordinary knowledge in the art. The inventive concept may be embodied in various forms without being limited to the exemplary embodiments set forth herein.

### EXAMPLES

In the following experiments, the weight average molecular weight of the polymer was measured by gel permeation chromatography (GPC), which utilized Waters 410 and a refractive index detector as the analysis instrument, polystyrene as a calibration standard, THF as an eluent, HR3,4 as a column, and 10 mg/4 mL THF as a polymer sample concentration.

In the following experiments, the viscosity of the package material was measured according to the standard ASTM D4287. The Tg of the package film was measured according to the standard ASTM D7028. The thermal expansion coefficient of the package film was measured according to the standard ASTM D6745. The storage modulus of the package at 25° C. was measured according to the standard ASTM D7028. The warpage of the wafer was measured according to the standard ASTM F1390. The flow mark of the package material was observed with the human eye. Checking whether or not the wafer was filled by the package material was performed by the human eye.

### Synthesis Example 1 (MQP-1)

17.5 g of siloxane resin (silanol-trimethyl silyl modified Q resin, SQO-299 commercially available from Gelest, MW: 3000-4000) was added to the solution of 60 g of toluene and 15 g of ethanol, and stirred at room temperature to be dissolved. 13.8 g of hydroxy terminated siloxane compound (silanol terminated polydimethyl siloxane, S12 commercially available from Gelest, MW: 400-700) was added to the solution, and 0.3 g of NaOH aqueous solution (0.5N) was then added to the solution. The solution was then refluxed at 70° C. for 16 hours to perform a sol-gel reaction, and S12/SQO-299 had a molar ratio of 5/1.

Subsequently, 4.3 g of epoxy silane (2-(3,4-Epoxycyclohexyl)ethyl]trimethoxysilane, KBM-303 commercially available from Shin-Etsu Chemical Co., Ltd.) and 0.18 g of deionized water were added to the above reaction, and further refluxed at 70° C. for 16 hours. A phase inversion tube was then set to react at 100° C. for further 16 hours. The solvent was then removed to obtain MQP-1 sample. KBM-303/SQO-299 had a molar ratio of 4/1. The reaction was shown below. Note that the following formula and chemical structures only illustrates the reactions between the functional groups of the siloxane resin, the hydroxy terminated siloxane compound, and the epoxy silane, and the product structure of this Example is not limited thereto. For example, the number of the —OH groups of the siloxane resin was not limited to that in the following formula, and the hydroxy terminated siloxane compound and the siloxane resin could crosslink other than react to form the linear structure as in the following formula.

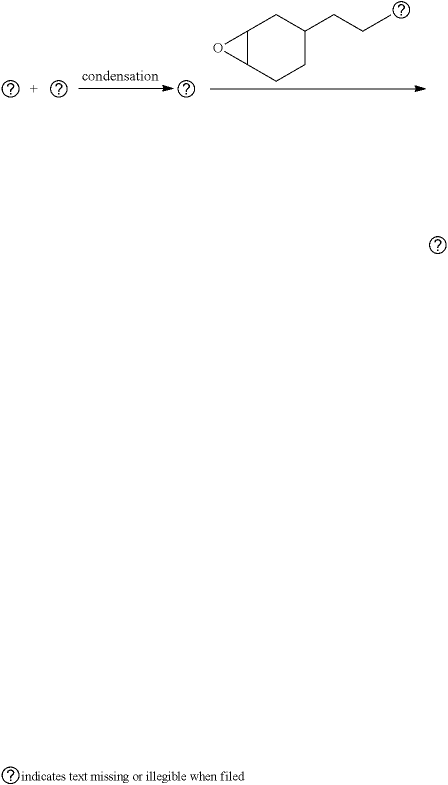

MQP-1 sample was dissolved CDCl₃ to analyze its ²⁹Si-NMR spectrum: chemical shift of disappear peaks (ppm): −8.4, −11.3, −19.4, and −20.3 (belong to S12); and −41.5 (belong to KBM-303). Chemical shift of new peaks (ppm): −13.1 and −22.3 (belong to S12); and 6.9. In ²⁹Si-NMR spectrum, the chemical shift of the disappear peak at −41 ppm should be caused from the Si—O—CH₃ bondings in KBM-303 being disappeared through the sol-gel reaction. The existence of epoxy groups in MQP-1 sample was proven by ¹H NMR. It is speculated that the silane in KBM-303 formed bondings. In addition, MQP-1 sample had a weight average molecular weight of about 7000.

### Synthesis Example 2 (MQP-2)

17.5 g of siloxane resin (SQO-299) was added to the solution of 60 g of toluene and 15 g of ethanol, and stirred at room temperature to be dissolved. 27.5 g of hydroxy terminated siloxane compound (silanol terminated polydimethyl siloxane, S14 commercially available from Gelest, MW: 700-1500) was added to the solution, and 0.3 g of NaOH aqueous solution (0.5N) was then added to the solution. The solution was then refluxed at 70° C. for 16 hours to perform a sol-gel reaction, and S14/SQO-299 had a molar ratio of 5/1.

Subsequently, 4.3 g of epoxy silane (KBM-303) and 0.18 g of deionized water were added to the above reaction, and further refluxed at 70° C. for 16 hours. A phase inversion tube was then set to react at 100° C. for further 16 hours. The solvent was then removed to obtain MQP-2 sample. KBM-303/SQO-299 had a molar ratio of 4/1.

MQP-2 sample was dissolved CDCl₃ to analyze its ²⁹Si-NMR spectrum: chemical shift of disappear peaks (ppm): −8.4, −11.3, −19.4, and −20.3 (belong to S14); and −41.5 (belong to KBM-303). Chemical shift of new peaks (ppm): −13.1 and −22.3 (belong to S14); and 6.9. In ²⁹Si-NMR spectrum, the chemical shift of the disappear peak at −41 ppm should be caused from the Si—O—CH₃ bondings in KBM-303 being disappeared through the sol-gel reaction. The existence of epoxy groups in MQP-2 sample was proven by ¹H NMR. It is speculated that the silane in KBM-303 formed bondings. In addition, MQP-2 sample had a weight average molecular weight of about 10000.

### Synthesis Example 3 (MQP-3)

17.5 g of siloxane resin (SQO-299) was added to the solution of 60 g of toluene and 15 g of ethanol, and stirred at room temperature to be dissolved. 13.8 g of hydroxy terminated siloxane compound (S12) was added to the solution, and 0.3 g of NaOH aqueous solution (0.5N) was then added to the solution. The solution was then refluxed at 70° C. for 16 hours to perform a sol-gel reaction, and S12/SQO-299 had a molar ratio of 5/1.

Subsequently, 4.1 g of epoxy silane (Glycidoxypropyltrimethoxysilane, Z-6040 commercially available from Dow Chemical Company) and 0.18 g of deionized water were added to the above reaction, and further refluxed at 70° C. for 16 hours. A phase inversion tube was then set to react at 100° C. for further 16 hours. The solvent was then removed to obtain MQP-3 sample. Z-6040/SQO-299 had a molar ratio of 4/1. In addition, MQP-3 sample had a weight average molecular weight of about 7300.

### Synthesis Example 4 (MQP-4)

17.5 g of siloxane resin (SQO-299) was added to the solution of 60 g of toluene and 15 g of ethanol, and stirred at room temperature to be dissolved. 13.8 g of hydroxy terminated siloxane compound (S12) and 4.3 g of epoxy silane (KBM-303) was added to the solution, and 0.3 g of NaOH aqueous solution (0.5N) was then added to the solution. The solution was then refluxed at 70° C. for 16 hours to perform a sol-gel reaction. Subsequently, 0.18 g of deionized water was added to the above reaction, and a phase inversion tube was then set to react at 100° C. for further 16 hours. The solvent was then removed to obtain MQP-4 sample. S12/SQO-299 had a molar ratio of 5/1, and KBM-303/SQO-299 had a molar ratio of 4/1. In addition, MQP-4 sample had a weight average molecular weight of about 1300, which is obviously lower than the weight average molecular weight of the products in Synthesis Examples 1 to 3.

### Synthesis Example 5 (MQP-5)

17.5 g of siloxane resin (SQO-299) was added to the solution of 60 g of toluene and 15 g of ethanol, and stirred at room temperature to be dissolved. 27.5 g of hydroxy terminated siloxane compound (S14) and 4.3 g of epoxy silane (KBM-303) was added to the solution, and 0.3 g of NaOH aqueous solution (0.5N) was then added to the solution. The solution was then refluxed at 70° C. for 16 hours to perform a sol-gel reaction. Subsequently, 0.18 g of deionized water was added to the above reaction, and a phase inversion tube was then set to react at 100° C. for further 16 hours. The solvent was then removed to obtain MQP-5 sample. S14/SQO-299 had a molar ratio of 5/1, and KBM-303/SQO-299 had a molar ratio of 4/1. In addition, MQP-5 sample had a weight average molecular weight of about 2300, which is obviously lower than the weight average molecular weight of the products in Synthesis Examples 1 to 3.

### Synthesis Example 6 (MQP-6)

17.5 g of siloxane resin (SQO-299) was added to the solution of 60 g of toluene and 15 g of ethanol, and stirred at room temperature to be dissolved. 5.5 g of hydroxy terminated siloxane compound (S12) was added to the solution, and 0.3 g of NaOH aqueous solution (0.5N) was then added to the solution. The solution was then refluxed at 70° C. for 16 hours to perform a sol-gel reaction, and S12/SQO-299 had a molar ratio of 2/1.

Subsequently, 4.3 g of epoxy silane (KBM-303) and 0.18 g of deionized water were added to the above reaction, and further refluxed at 70° C. for 16 hours. A phase inversion tube was then set to react at 100° C. for further 16 hours. The solvent was then removed to obtain MQP-6 sample. KBM-303/SQO-299 had a molar ratio of 4/1. In addition, MQP-6 sample had a weight average molecular weight of about 4100, which is obviously lower than the weight average molecular weight of the products in Synthesis Examples 1 to 3.

### Synthesis Example 7 (MQP-7)

17.5 g of siloxane resin (SQO-299) was added to the solution of 60 g of toluene and 15 g of ethanol, and stirred at room temperature to be dissolved. 11 g of hydroxy terminated siloxane compound (S12) was added to the solution, and 0.3 g of NaOH aqueous solution (0.5N) was then added to the solution. The solution was then refluxed at 70° C. for 16 hours to perform a sol-gel reaction, and S12/SQO-299 had a molar ratio of 4/1.

Subsequently, 4.3 g of epoxy silane (KBM-303) and 0.18 g of deionized water were added to the above reaction, and further refluxed at 70° C. for 16 hours. A phase inversion tube was then set to react at 100° C. for further 16 hours. The solvent was then removed to obtain MQP-7 sample. KBM-303/SQO-299 had a molar ratio of 4/1. In addition, MQP-7 sample had a weight average molecular weight of about 6200, which is slightly lower than the weight average molecular weight of the products in Synthesis Examples 1 to 3.

### Example 1

10.9 g of cycloaliphatic epoxy resin (2021P commercially available from ECLAT, epoxy equivalent was 136), 2.9 g of naphthalene based epoxy resin (4032D commercially available from DIC, epoxy equivalent was 143), 0.7 g of MQP-1 sample, 14.9 g of anhydride curing agent (methyltetrahydrophthalic anhydride, MTHPA), 0.9 g of accelerator (U-cat 5002 commercially available from San APRO), 0.3 g of coupling agent (KBM-303), and 0.3 g of carbon black (Lamp black® 101 commercially available from Degussa) were stirred and mixed at room temperature.

670 g of inorganic powder (silica powder commercially available from Admatech, d₅₀=20 μm) was added to the above mixture and mixed to form a package material with a viscosity of 520 Pa·s. The package material was coated onto a wafer and heated to be cured to form a package film. The package film had a glass transition temperature (Tg) of 158° C., a thermal expansion temperature of 9 ppm/° C., and a storage modulus of 21 GPa at 25° C., and a wafer warpage amount of less than 1 mm. Flow mark was not observed, and region on the wafer being not filled with the package material was not observed. Accordingly, the package material had an excellent flowability.

### Example 2

10.9 g of cycloaliphatic epoxy resin (2021P), 2.9 g of naphthalene based epoxy resin (4032D), 2.1 g of MQP-1 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 537 Pa·s. The package material was coated onto a wafer and heated to be cured to form a package film. The package film had Tg of 160° C., a thermal expansion temperature of 9 ppm/° C., and a storage modulus of 19 GPa at 25° C., and a wafer warpage amount of less than 1 mm. Flow mark was not observed, and region on the wafer being not filled with the package material was not observed. Accordingly, the package material had an excellent flowability.

### Example 3

10.9 g of cycloaliphatic epoxy resin (2021P), 2.9 g of naphthalene based epoxy resin (4032D), 3.5 g of MQP-1 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 559 Pa·s. The package material was coated onto a wafer and heated to be cured to form a package film. The package film had Tg of 161° C., a thermal expansion temperature of 9 ppm/° C., and a storage modulus of 18 GPa at 25° C., and a wafer warpage amount of less than 1 mm. Flow mark was not observed, and region on the wafer being not filled with the package material was not observed. Accordingly, the package material had an excellent flowability.

### Example 4

10.9 g of cycloaliphatic epoxy resin (2021P), 2.9 g of naphthalene based epoxy resin (4032D), 0.7 g of MQP-3 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 528 Pa·s. The package material was coated onto a wafer and heated to be cured to form a package film. The package film had Tg of 157° C., a thermal expansion temperature of 9 ppm/° C., and a storage modulus of 21 GPa at 25° C., and a wafer warpage amount of less than 1 mm. Flow mark was not observed, and region on the wafer being not filled with the package material was not observed. Accordingly, the package material had an excellent flowability.

### Example 5

10.9 g of cycloaliphatic epoxy resin (2021P), 2.9 g of naphthalene based epoxy resin (4032D), 0.7 g of MQP-1 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

300 g of silica powder (commercially available from Admatech) was added to the above mixture and mixed to form a package material with a viscosity of 540 Pa·s. The package material was coated onto a wafer and heated to be cured to form a package film. The package film had Tg of 160° C., a thermal expansion temperature of 16 ppm/° C., and a storage modulus of 11 GPa at 25° C., and a wafer warpage amount of less than 1 mm. Flow mark was not observed, and region on the wafer being not filled with the package material was not observed. Accordingly, the package material had an excellent flowability.

### Example 6

10.9 g of cycloaliphatic epoxy resin (2021P), 2.9 g of naphthalene based epoxy resin (4032D), 0.7 g of MQP-2 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 525 Pa·s. The package material was coated onto a wafer and heated to be cured to form a package film. The package film had Tg of 158° C., a thermal expansion temperature of 9 ppm/° C., and a storage modulus of 20 GPa at 25° C., and a wafer warpage amount of less than 1 mm. Flow mark was not observed, and region on the wafer being not filled with the package material was not observed. Accordingly, the package material had an excellent flowability.

### Example 7

10.9 g of cycloaliphatic epoxy resin (2021P), 2.9 g of naphthalene based epoxy resin (4032D), 2.1 g of MQP-2 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 548 Pa·s. The package material was coated onto a wafer and heated to be cured to form a package film. The package film had Tg of 156° C., a thermal expansion temperature of 9 ppm/° C., and a storage modulus of 18 GPa at 25° C., and a wafer warpage amount of less than 1 mm. Flow mark was not observed, and region on the wafer being not filled with the package material was not observed. Accordingly, the package material had an excellent flowability.

### Example 8

10.9 g of cycloaliphatic epoxy resin (2021P), 2.9 g of naphthalene based epoxy resin (4032D), 3.5 g of MQP-2 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 563 Pa·s. The package material was coated onto a wafer and heated to be cured to form a package film. The package film had Tg of 157° C., a thermal expansion temperature of 9 ppm/° C., and a storage modulus of 18 GPa at 25° C., and a wafer warpage amount of less than 1 mm. Flow mark was not observed, and region on the wafer being not filled with the package material was not observed. Accordingly, the package material had an excellent flowability.

### Comparative Example 1

10.9 g of cycloaliphatic epoxy resin (2021P), 2.9 g of naphthalene based epoxy resin (4032D), 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 480 Pa·s. The package material was coated onto a wafer and heated to be cured to form a package film. The package film had Tg of 161° C., a thermal expansion temperature of 10 ppm/° C., and a storage modulus of 25 GPa at 25° C., and a wafer warpage amount of 3 mm. Flow mark was not observed, and region on the wafer being not filled with the package material was not observed. Accordingly, the package material had an excellent flowability.

### Comparative Example 2

10.9 g of cycloaliphatic epoxy resin (2021P), 2.9 g of naphthalene based epoxy resin (4032D), 0.53 g of MQP-1 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 514 Pa·s. The package material was coated onto a wafer and heated to be cured to form a package film. The package film had Tg of 159° C., a thermal expansion temperature of 9 ppm/° C., and a storage modulus of 22 GPa at 25° C., and a wafer warpage amount of 1.5 mm. Flow mark was not observed, and region on the wafer being not filled with the package material was not observed. Accordingly, the package material had an excellent flowability.

### Comparative Example 3

10.9 g of cycloaliphatic epoxy resin (2021P), 2.9 g of naphthalene based epoxy resin (4032D), 3.85 g of MQP-1 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 681 Pa·s. The package material was coated onto a wafer and heated to be cured to form a package film. The package film had Tg of 161° C., a thermal expansion temperature of 9 ppm/° C., and a storage modulus of 18 GPa at 25° C., and a wafer warpage amount of less than 1 mm. Flow mark was observed, and region on the wafer being not filled with the package material was observed. Accordingly, the package material had a poor flowability.

### Comparative Example 4

10.9 g of cycloaliphatic epoxy resin (2021P), 2.9 g of naphthalene based epoxy resin (4032D), 0.53 g of MQP-2 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 525 Pa·s. The package material was coated onto a wafer and heated to be cured to form a package film. The package film had Tg of 158° C., a thermal expansion temperature of 9 ppm/° C., and a storage modulus of 21 GPa at 25° C., and a wafer warpage amount of 1.5 mm. Flow mark was not observed, and region on the wafer being not filled with the package material was not observed. Accordingly, the package material had an excellent flowability.

### Comparative Example 5

10.9 g of cycloaliphatic epoxy resin (2021P), 2.9 g of naphthalene based epoxy resin (4032D), 3.85 g of MQP-2 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 710 Pa·s. The package material was coated onto a wafer and heated to be cured to form a package film. The package film had Tg of 162° C., a thermal expansion temperature of 9 ppm/° C., and a storage modulus of 18 GPa at 25° C., and a wafer warpage amount of less than 1 mm. Flow mark was observed, and region on the wafer being not filled with the package material was observed. Accordingly, the package material had a poor flowability.

### Comparative Example 6

10.9 g of cycloaliphatic epoxy resin (2021P), 2.9 g of naphthalene based epoxy resin (4032D), 0.7 g of MQP-4 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 491 Pa·s. The package material was coated onto a wafer and heated to be cured to form a package film. The package film had Tg of 160° C., a thermal expansion temperature of 9 ppm/° C., and a storage modulus of 24 GPa at 25° C., and a wafer warpage amount of 2 mm. Flow mark was observed, and region on the wafer being not filled with the package material was observed. Accordingly, the package material had a poor flowability.

### Comparative Example 7

10.9 g of cycloaliphatic epoxy resin (2021P), 2.9 g of naphthalene based epoxy resin (4032D), 0.7 g of MQP-5 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 512 Pa·s. The package material was coated onto a wafer and heated to be cured to form a package film. The package film had Tg of 159° C., a thermal expansion temperature of 9 ppm/° C., and a storage modulus of 24 GPa at 25° C., and a wafer warpage amount of 2.5 mm. Flow mark was not observed, and region on the wafer being not filled with the package material was not observed. Accordingly, the package material had an excellent flowability.

### Comparative Example 8

10.9 g of cycloaliphatic epoxy resin (2021P), 2.9 g of naphthalene based epoxy resin (4032D), 0.7 g of MQP-6 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 502 Pa·s. The package material was coated onto a wafer and heated to be cured to form a package film. The package film had Tg of 159° C., a thermal expansion temperature of 9 ppm/° C., and a storage modulus of 21 GPa at 25° C., and a wafer warpage amount of 2 mm. Flow mark was observed, and region on the wafer being not filled with the package material was observed. Accordingly, the package material had a poor flowability.

### Comparative Example 9

10.9 g of cycloaliphatic epoxy resin (2021P), 2.9 g of naphthalene based epoxy resin (4032D), 0.7 g of MQP-7 sample, 14.9 g of anhydride curing agent (MTHPA), 0.9 g of accelerator (U-cat 5002), 0.3 g of coupling agent (KBM-303), and 0.3 g of carbon black (Lamp black® 101) were stirred and mixed at room temperature.

670 g of silica powder (commercially available from Admatech) was added to the above mixture and mixed to form a package material with a viscosity of 518 Pa·s. The package material was coated onto a wafer and heated to be cured to form a package film. The package film had Tg of 159° C., a thermal expansion temperature of 9 ppm/° C., and a storage modulus of 21 GPa at 25° C., and a wafer warpage amount of 1.5 mm. Flow mark was observed, and region on the wafer being not filled with the package material was observed. Accordingly, the package material had a poor flowability.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. An epoxy-containing siloxane-modified resin,
formed by reacting a hydroxy terminated siloxane compound with a siloxane resin, and then reacting with an epoxy silane;
wherein the hydroxy terminated siloxane compound and the siloxane resin have a molar ratio of 5:1 to 10:1, and the epoxy silane and the siloxane resin have a molar ratio of 2:1 to 4:1.

2. The epoxy-containing siloxane-modified resin as claimed in claim 1, wherein the hydroxy terminated siloxane resin has a chemical structure of 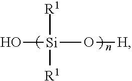
wherein each R¹ is independently C₁₋₅ alkyl group or 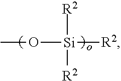
each R² is independently C₁₋₅ alkyl group, n is 5-20, and o is 5-20.

3. The epoxy-containing siloxane-modified resin as claimed in claim 1, wherein the siloxane resin has a chemical formula of R³₃SiO_{4/2}SiO_{3/2}SiOH, wherein R³ is C₁₋₆ alkyl group or phenyl group.

4. The epoxy-containing siloxane-modified resin as claimed in claim 1, wherein the epoxy silane has a chemical structure of 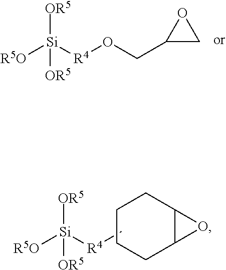
wherein R⁴ is C₁₋₅ alkylene group, and each R⁵ is independently C₁₋₅ alkyl group.

5. The epoxy-containing siloxane-modified resin as claimed in claim 1, having a weight average molecular weight of 7000 to 10000.

6. A package material, comprising:
(a) 1 part by weight of epoxy-containing siloxane-modified resin;
(b) 3 to 30 parts by weight of epoxy resin;
(c) 3 to 30 parts by weight of anhydride curing agent; and
(d) 50 to 500 parts by weight of inorganic powder,
wherein (a) epoxy-containing siloxane-modified resin is formed by reacting a hydroxy terminated siloxane compound with a siloxane resin, and then reacting with an epoxy silane;
wherein the hydroxy terminated siloxane compound and the siloxane resin have a molar ratio of 5:1 to 10:1, and the epoxy silane and the siloxane resin have a molar ratio of 2:1 to 4:1.

7. The package material as claimed in claim 6, wherein (b) epoxy resin comprises bisphenol A epoxy resin, bisphenol F epoxy resin, cycloaliphatic epoxy resin, novolac resin, naphthalene based epoxy resin, or a combination thereof.

8. The package material as claimed in claim 6, wherein (c) anhydride curing agent comprises methylhexahydrophthalic anhydride, methyltetrahydrophthalic anhydride, hexahydrophthalic anhydride, benzophenonetetracarboxylic dianhydride, or a combination thereof.

9. The package material as claimed in claim 6, wherein (d) inorganic powder includes silica powder or alumina powder of sub-micrometer scale to micrometer scale.

10. The package material as claimed in claim 6, further comprising (e) 0.2 to 2 parts by weight of accelerator.

11. The package material as claimed in claim 10, wherein (e) accelerator comprises 2-methyl imidazole, 2-ethyl-4-methyl imidazole, triethylamine, triphenyl phosphine, or a combination thereof.

12. The package material as claimed in claim 6, further comprising (f) 0.1 to 0.8 parts by weight of coupling agent.

13. The package material as claimed in claim 12, wherein (f) coupling agent comprises glycidyloxypropyltrimethoxysilane, trimethoxy[2-(7-oxabicyclo[4.1.0]hept-3-yl)ethyl]silane, or a combination thereof.

14. A package structure, comprising:
a wafer;
a package film covering the wafer,
wherein the package film is formed by curing a package material,
wherein the package material includes:
(a) 1 part by weight of epoxy-containing siloxane-modified resin;
(b) 3 to 30 parts by weight of epoxy resin;
(c) 3 to 30 parts by weight of anhydride curing agent; and
(d) 50 to 500 parts by weight of inorganic powder,
wherein (a) epoxy-containing siloxane-modified resin is formed by reacting a hydroxy terminated siloxane compound with a siloxane resin, and then reacting with an epoxy silane;
wherein the hydroxy terminated siloxane compound and the siloxane resin have a molar ratio of 5:1 to 10:1, and the epoxy silane and the siloxane resin have a molar ratio of 2:1 to 4:1.

15. The package structure as claimed in claim 14, wherein the package material further comprises (e) 0.2 to 2 parts by weight of accelerator.

16. The package structure as claimed in claim 14, wherein the package material further comprises (f) 0.1 to 0.8 parts by weight of coupling agent.
